(19) United States
(12) Patent Application Publication
(10) Pub. No.: US 2002/0125578 A1
(43) Pub. Date: Sep. 12, 2002

(54) Easily peelable sheet having contact plates and switch device employing the same

(75) Inventor: Naoya Iwama, Miyagi-ken (JP)

Correspondence Address: BEYER WEAVER & THOMAS LLP, P.O. BOX 778, BERKELEY, CA, 94704-0778, US

(73) Assignee: ALPS ELECTRIC CO., LTD

(21) Appl. No.: 10/060,832

(22) Filed: Jan. 29, 2002

(30) Foreign Application Priority Data
Mar. 8, 2001 (JP) 2001-065778

(51) Int. Cl. H01L 31/00

(52) U.S. Cl. 257/774

(57) ABSTRACT

The present invention comprises: a strip-shaped peel sheet; a spacer sheet stuck onto the peel sheet via an adhesive layer; an upper face sheet stuck onto an upper face of the spacer sheet via an adhesive layer; and contact plates stuck to the upper face sheet, wherein, on the peel sheet and the spacer sheet, penetration holes through which the contact plates can penetrate, and coupling grooves by which adjacent penetration holes are coupled are formed, wherein, of the coupling grooves, one side of the coupling groove provided in a direction crossing a feed direction of the strip-shaped peel sheet continues to rear ends of inner circumferences of the adjacent penetration holes with respect to the feed direction of the peel sheet.

### BACKGROUND OF THE INVENTION

1. Field of the Invention

The present invention relates to a sheet having contact plates used as a key switch for operating digital communication equipment such as portable phone, and the structure of a switch employing the same.

2. Description of the Prior Art

The structure of a conventional switch sheet is shown in FIGS. 6 to 8. FIG. 6 is an exploded perspective view showing the switch sheet. FIG. 7 is a plan view showing details of penetration holes. FIG. 8 is a side view of FIG. 7.

A conventional switch sheet comprises: a peel sheet 11 formed into a strip shape and having feed guide holes 11a provided at a fixed interval at both sides of a longitudinal direction X (feed direction); a rectangular spacer sheet 13 stuck to a separate face of the peel sheet 11 via an adhesive layer; and a rectangular upper face sheet 14 stuck to an upper face of the spacer sheet 13 via an adhesive layer.

On the peel sheet 11 and the spacer sheet 13, plural penetration holes 13a are formed which penetrate contact plates formed by expanding thin metal plates in a dome shape and make it possible to stick the dome tops of the contact plates to a lower face of the upper face sheet 14 via an adhesive layer. Coupling grooves 13b and 13c are provided to couple adjacent penetration holes 13a of the plural penetration holes 13a.

The coupling grooves 13b and 13c are provided at about the center of the penetration holes 13a. By providing the coupling grooves 13b and 13c, when the dome-shaped contact plates are pushed, air within the domes can be expelled to other penetration holes 13a through the coupling grooves 13b and 13c, providing stable operability.

The coupling grooves 13b and 13c are formed from vertical coupling grooves 13c formed along the longitudinal direction X (feed direction) of the peel sheet 11 and the spacer sheet 13, and horizontal coupling grooves 13b formed along a direction Y crossing the longitudinal direction (feed direction).

However, in the structure of the above-described conventional switch sheet, the switch sheet is mounted on a circuit board in such a way that, while pulling out the stripe-shaped peel sheet 11 in the feed direction X, the peel sheet 11 is peeled off with the spacer sheet 13 and the upper face sheet 14 being overlaid, and the separated spacer sheet 13 and upper face sheet 14 are stuck onto the circuit board.

In this case, as shown in FIGS. 7 and 8, in the conventional switch sheet, since the coupling grooves 13b and 13c are formed at about the center of the penetration holes 13a, at both sides of the coupling grooves 13b and 13c, protrusions 13d exist toward a coupling part from an inner circumferential end of the penetration holes 13a. In the case where the coupling grooves 13b and 13c are formed in the direction Y crossing the longitudinal direction X (feed direction) of the peel sheet 11, since the protrusions 13d on a peel face between the spacer sheet 13 and the peel sheet 11 protrude from an inner circumferential end of the penetration holes 13a, the protrusions 13d remain unpeeled, so that it is difficult to peel the peel sheet 11 from the spacer sheet 13 in the vicinity of the protrusions 13. This has been a problem of the conventional switch sheet.

In the case where all the coupling grooves 13b and 13c are formed along the longitudinal direction X (feed direction) of the peel sheet 11, the position of the penetration holes 13a, that is, the layout of contact plates is limited. This has been another problem of the conventional switch sheet.

### SUMMARY OF THE INVENTION

The present invention solves the above-described problems and provides a sheet having contact plates that allows a peel sheet thereof to be smoothly peeled from a spacer sheet and provides greater freedom in the layout of the contact plates, and a switch device employing the same.

To solve the above-described problems, as first means, the present invention comprises: a strip-shaped peel sheet; a spacer sheet stuck onto the peel sheet via an adhesive layer; an upper face sheet stuck onto an upper face of the spacer sheet via an adhesive layer; and contact plates stuck to the upper face sheet, wherein, on the peel sheet and the spacer sheet, penetration holes through which the contact plates can penetrate, and coupling grooves by which the adjacent penetration holes are coupled are formed, wherein, of the coupling grooves, one side of the coupling grooves provided in a direction crossing a feed direction of the strip-shaped peel sheet continues to rear ends of inner circumferences of the adjacent penetration holes with respect to the feed direction of the peel sheet of the adjacent penetration holes.

As second means, one side of the coupling grooves continues linearly or curvedly.

As third means, a coupling part at another side of the coupling grooves coupling the penetration holes is formed in an arc shape.

As fourth means, the spacer sheet and the upper face sheet are formed rectangularly and are mounted so that short sides of the rectangles are in the feed direction of the strip-shaped peel sheet, and wherein the penetration holes disposed at a side of a long side of the spacer sheet are coupled by the coupling grooves.

As fifth means, the coupling grooves are formed from first coupling grooves coupling the penetration holes disposed at the side of the long side of the spacer sheet and second coupling grooves coupling the penetration holes disposed at a side of the short side of the spacer sheet.

As sixth means, a sheet having contact plates comprising one of the first to fifth means and a circuit board on which plural fixed contacts are disposed are provided, a peel sheet of the sheet having contact plates is peeled, and the sheet having the contact plates from which the peel sheet has been peeled is stuck onto the circuit board on which plural fixed contacts are disposed, by an adhesive layer of the spacer sheet so that the contact plates are opposite to the fixed contacts.

### BRIEF DESCRIPTION OF THE DRAWINGS

Preferred embodiments of the present invention will be described in detail based on the followings, wherein:

FIG. 1 is a drawing showing a roll of a peel sheet of a sheet having contact plates according to one embodiment of the present invention;

FIG. 2 is a plan view showing the sheet having contact plates of the present invention from which the peel sheet is removed;

FIG. 3 is a plan view showing the sheet having contact plates of the present invention from which the peel sheet is removed;

FIG. 4 is an exploded perspective view showing a switch device employing the sheet having contact plates of the present invention;

FIG. 5 is a partial sectional view showing the vicinity of a contact plate of the sheet having contact plates of the present invention;

FIG. 6 is an exploded perspective view showing a conventional switch sheet;

FIG. 7 is a plan view showing partial details of penetration holes; and

FIG. 8 is a side view showing partial details of a penetration hole of a conventional switch sheet.

### DESCRIPTION OF THE PREFERRED EMBODIMENTS

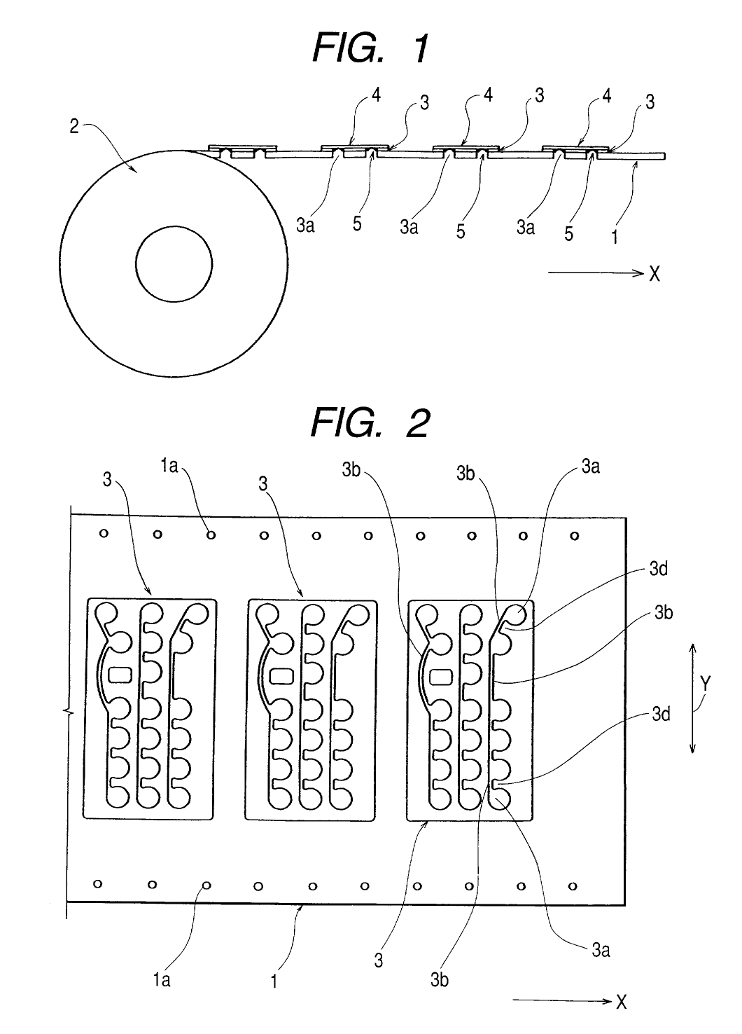

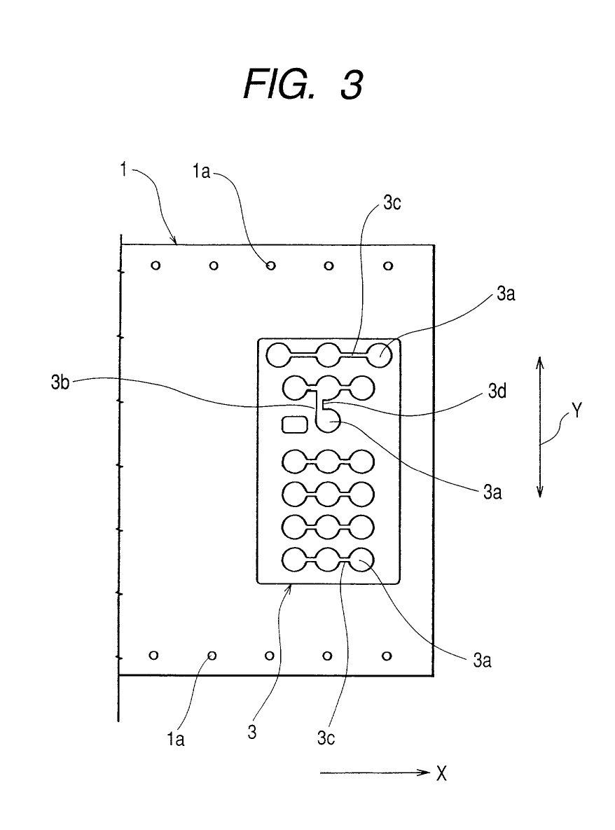

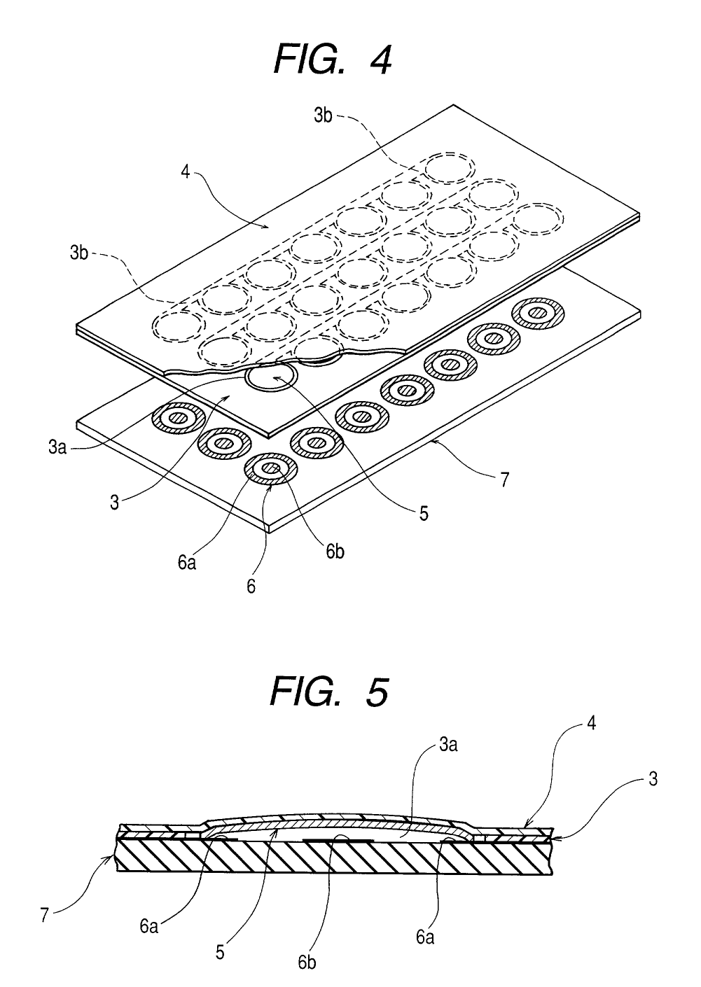

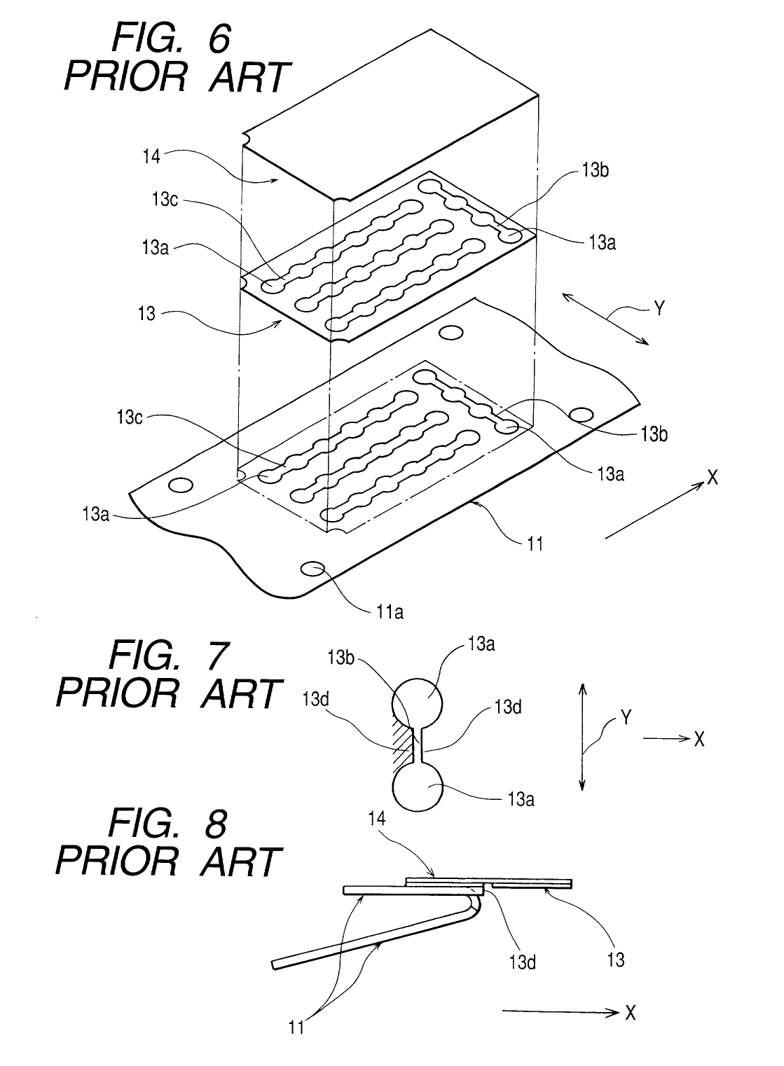

Hereinafter, one embodiment of the present invention is shown in FIGS. 1 to 5. FIG. 1 is a drawing showing a roll of a peel sheet of a sheet having contact plates. FIGS. 2 and 3 are plan views showing the sheet having contact plates from which the peel sheet is removed. FIG. 4 is an exploded perspective view showing a switch device employing a sheet having contact plates. FIG. 5 is a partial sectional view showing the vicinity of a contact plate of the same.

In FIGS. 1 to 3, the peel sheet 1 is formed in a strip shape with a thin resin sheet. In the peel sheet 1, feed guide holes la are continuously formed at a fixed interval at both sides along a longitudinal (feed) direction X, and the guide holes la are used as guide holes of pins for feeding a carriage sheet when the peel sheet 1 wound around a rotation reel 2 is removed by an automatic assembling machine or the like.

A rectangular spacer sheet 3 is stuck onto a separate face at the center of the peel sheet 1 via an adhesive layer. A rectangular upper face sheet 4 is stuck onto an upper face of the spacer sheet 3 via an adhesive layer. In this case, the spacer sheet 3 and the upper face sheet 4 are stuck so that the short side of the rectangles is in the longitudinal (feed) direction X of the strip-shaped peel sheet 1.

The spacer sheet 3 is formed rectangularly with a thin resin sheet. At the center of the spacer sheet 3, penetration holes 3a through which contact plates 5 described later can penetrate are formed as on the peel sheet 1. The penetration holes 3a are formed with plural coupling grooves 3b and 3c to couple adjacent penetration holes 3a. The coupling grooves 3b and 3c are formed from first coupling grooves 3b for coupling the penetration holes 3a disposed at the side of the long side of the spacer sheet 3, and coupling grooves 3c for coupling the penetration holes 3a disposed at the side of the short side of the spacer sheet 3.

FIG. 2 shows a case where only the first coupling 7 grooves 3b of the coupling grooves 3b and 3c are formed in the peel sheet 1 and the spacer sheet 3, and FIG. 3 shows a case where both the first coupling grooves 3b and the second coupling grooves 3c are formed.

By providing the coupling grooves 3b and 3c, when dome-shaped contact plates 5 described later are pushed, air within the domes can be expelled to other penetration holes 3a through the coupling grooves 3b and 3c, providing stable switch operability. of the coupling grooves 3b and 3c, the second coupling grooves 3c provided along the longitudinal (feed) direction X of the stripe-shaped peel sheet 1 are formed at a center between adjacent penetration holes 3a, while the first coupling grooves 3b provided in a direction Y crossing the longitudinal (feed) direction X of the stripe-shaped peel sheet 1, without being formed at the center of the penetration holes 3a, are shifted so that one side thereof continues linearly or curvedly at the rear ends of the inner circumferences of the adjacent penetration holes 3a with respect to the longitudinal (feed) direction X of the peel sheet 1.

Although the coupling parts 3d at the other side of the first coupling grooves 3b for coupling the penetration holes 3a protrude from the inner circumferential end of the penetration holes 3a, the coupling parts 3d are also formed in an arc shape so that the peel sheet 1 can be easily peeled.

The contact plates 5 are formed by expanding conductive thin metal plates in a dome shape and inserted in penetration holes 3a of the peel sheet 1 and the spacer sheet 3, and their dome tops are stuck to the lower face of the upper sheet 4 via an adhesive layer. The sheet having contact plates is constructed with the plural contact plates 5 being held by the spacer sheet 3 and the upper face sheet 4.

FIGS. 4 and 5 show the structure of a switch device formed by sticking the sheet having contact plates peeled from the peel sheet 1 onto a circuit board 7 on which plural fixed contacts 6 are disposed, via an adhesive layer of the spacer sheet 3.

The circuit board 7 is formed from a multilayer plate such as insulative resin, and plural fixed contacts 6 constructed from copper foil, carbon, or the like are formed on the surface of the circuit board 7. The fixed contact 6 is formed from a ring-like peripheral contact 6a and a central contact 6b placed at the center of the peripheral contact 6a wherein a margin of the dome-shaped contact plate 5 contacts the peripheral contact 6a and the center of the dome faces the central contact 6b.

A description is made of a method of assembling the switch device employing the sheet having contact plates. As shown in FIG. 1, the sheet having contact plates wound around the rotation reel 2 is fed in the pull-out (feed) direction X of the peel sheet 1 along the guide holes 1a by a feeding mechanism such as an automatic machine not shown.

Next, the peel sheet 1 is wound up by a winding reel not shown, the spacer sheet 3 and the upper face sheet 4 by which the contact plates 5 are held are peeled from the peel sheet 1 and are stuck onto the circuit board 7 on which the plural fixed contacts 6 are disposed, via an adhesive layer of the spacer sheet 3. Thus, the switch device has been assembled.

At this time, the coupling grooves 3b and 3c coupling the penetration holes 3a provided on the peel sheet 1 and the spacer sheet 3 are formed by shifting one side of the first coupling grooves 3b provided in the direction Y crossing the longitudinal (feed) direction X of the strip-shaped peel sheet 1 to the rear ends of the inner circumferences of the adjacent penetration holes 3a with respect to the longitudinal (feed) direction X of the peel sheet 1, that is, by making continuous the ends of the penetration holes 3a that are opposite to the feed direction X. With this construction, there are no protrusions from the ends of the penetration holes 3a that are opposite to the feed direction X to the feed direction, and there are no peel remains caused by protrusions, so that the peel sheet 1 can be smoothly peeled. Since one side of the first coupling grooves 3b continues linearly or curvedly, the construction is simplified and peeling is further facilitated. 10

The spacer sheet 3 and the upper face sheet 4 are formed rectangularly and are mounted so that the short side of the rectangles is in the longitudinal (feed) direction X of the strip-shaped peel sheet 1, and the penetration holes 3a disposed at the side of the long side of the spacer sheet 3 are coupled by the first coupling grooves 3b. By this construction, the first coupling grooves 3b can be used as air expelling grooves, operability is increased, and a withdrawal (feed) amount required for peeling from the peel sheet 1 can be reduced. Consequently, operation efficiency is increased.

As shown in FIG. 3, the coupling grooves 3b and 3c are formed from the first coupling grooves 3b coupling the penetration holes 3a disposed at the side of the long side of the spacer sheet 3 and the second coupling grooves 3c coupling the penetration holes 3a disposed at the side of the short side of the spacer sheet 3, wherein the short side of the spacer sheet 3 is in the longitudinal (feed) direction X of the strip-shaped peel sheet 1. By this construction, there occur no peel remains in the second grooves 3c, so that the peel sheet can be smoothly peeled, and by combining the first and second coupling grooves 3b and 3c, the contact plates 5 can be laid out with greater freedom.

As shown in FIG. 2, since the first coupling grooves 3b may be formed in the direction Y crossing the withdrawal (feed) direction X of the strip-shaped peel sheet 1, for example, the first coupling grooves 3b may be formed slantingly with respect to the withdrawal (feed) direction X. Also, in this case, the peel sheet 1 can be smoothly peeled, so that the contact plates 5 can be laid out with greater freedom.

As has been described above, a sheet having contact plates of the present invention comprises: a strip-shaped peel sheet; a spacer sheet stuck onto the peel sheet via an adhesive layer; an upper face sheet stuck onto the upper face of the spacer sheet via an adhesive layer; and contact plates stuck to the upper face sheet, wherein, on the peel sheet and the spacer sheet, penetration holes through which the contact plates can penetrate, and coupling grooves by which the adjacent penetration holes are coupled are formed, wherein, of the coupling grooves, one side of the coupling grooves provided in a direction crossing a feed direction of the strip-shaped peel sheet continues to the rear ends of the inner circumferences of the adjacent penetration holes with respect to the feed direction of the peel sheet. With this construction, there are no protrusions from the ends of the penetration holes that are opposite to the feed direction to the feed direction, and there are no peel remains caused by protrusions, so that the peel sheet can be smoothly peeled.

Since one side of the coupling grooves continues linearly or curvedly, the construction is simplified and peeling is further facilitated.

Since a coupling part at another side of the coupling grooves coupling the penetration holes is formed in an arc shape, the peel sheet is easily peeled also in the coupling part protruding from the ends of the inner circumferences of the penetration holes.

The spacer sheet and the upper face sheet are formed rectangularly and are mounted so that the short side of the rectangles is in the feed direction of the strip-shaped peel sheet, and the penetration holes disposed at the side of the long side of the spacer sheet are coupled by the coupling grooves. By this construction, the coupling grooves can be used as air expelling grooves, operability is increased, and a withdrawal (feed) amount required for peeling from the peel sheet can be reduced. Consequently, operation efficiency is increased.

The coupling grooves are formed from first coupling grooves coupling the penetration holes disposed at the side of the long side of the spacer sheet and second coupling grooves coupling the penetration holes disposed at the side of the short side of the spacer sheet, wherein the short side of the spacer sheet is in the longitudinal (feed) direction of the strip-shaped peel sheet. By this construction, there occur no peel remains in the second grooves, so that the peel sheet can be smoothly peeled, and by combining the first and second coupling grooves, the contact plates can be laid out with greater freedom.

A sheet having contact plates and a circuit board on which plural fixed contacts are disposed are provided, a peel sheet of the sheet having contact plates is peeled, and the sheet having contact plates from which the peel sheet has been peeled is stuck onto the circuit board on which plural fixed contacts are disposed, by an adhesive layer of the spacer sheet so that the contact plates are opposite to the fixed contacts. Therefore, a switch device having a simple construction and employing a sheet having contact plates can be easily formed.

What is claimed is:

1. A sheet having contact plates, comprising:
a strip-shaped peel sheet;
a spacer sheet stuck onto the peel sheet via an adhesive layer;
an upper face sheet stuck onto an upper face of the spacer sheet via an adhesive layer; and
contact plates stuck to the upper face sheet,
wherein, on the peel sheet and the spacer sheet, penetration holes through which the contact plates can penetrate, and coupling grooves by which the adjacent penetration holes are coupled are formed, wherein, of the coupling grooves, one side of the coupling grooves provided in a direction crossing a feed direction of the strip-shaped peel sheet continues to rear ends of inner circumferences of the adjacent penetration holes with respect to the feed direction of the peel sheet of the adjacent penetration holes.

2. The sheet having contact plates according to claim 1, wherein one side of the coupling grooves continues linearly or curvedly.

3. The sheet having contact plates according to claim 1, wherein a coupling part at another side of the coupling grooves coupling the penetration holes is formed in an arc shape.

4. The sheet having contact plates according to claim 1, wherein the spacer sheet and the upper face sheet are formed rectangularly and are mounted so that short sides of the rectangles are in the feed direction of the strip-shaped peel sheet, and wherein the penetration holes disposed at a side of a long side of the spacer sheet are coupled by the coupling grooves.

5. The sheet having contact plates according to claim 1, wherein the coupling grooves are formed from first coupling grooves coupling the penetration holes disposed at the side of the long side of the spacer sheet and second coupling grooves coupling the penetration holes disposed at a side of the short side of the spacer sheet.

6. A switch device comprising:
a sheet having contact plates according to claim 1; and
a circuit board on which plural fixed contacts are disposed,
wherein a peel sheet of the sheet having contact plates is peeled, and the sheet having the contact plates from which the peel sheet has been peeled is stuck onto the circuit board on which plural fixed contacts are disposed, by an adhesive layer of the spacer sheet so that the contact plates are opposite to the fixed contacts.

7. The switch device according to claim 6, wherein, in the sheet having contact plates, one side of the coupling grooves continues linearly or curvedly.

8. The switch device according to claim 6, wherein, in the sheet having contact plates, a coupling part at another side of the coupling grooves coupling the penetration holes is formed in an arc shape.
